(19) United States
(12) Patent Application Publication
(10) Pub. No.: US 2012/0107536 A1
(43) Pub. Date: May 3, 2012

(54) AMORPHOUS ALLOY HOUSING AND METHOD FOR MAKING SAME

(75) Inventors: YANG-YONG LI, Shenzhen City (CN); YI-MIN JIANG, Shenzhen City (CN); KAI LUO, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/084,628

(22) Filed: Apr. 12, 2011

(30) Foreign Application Priority Data
Oct. 28, 2010 (CN) 201010523400.2

(51) Int. Cl. B32B 1/02; C23C 14/06; C23C 14/48; C23C 16/30; C23C 16/34

(52) U.S. Cl. 428/34.6; 428/34.1; 427/248.1; 427/560; 427/530

(57) ABSTRACT

An amorphous alloy housing includes an amorphous alloy substrate and a wear-resistant protective layer formed on the amorphous alloy substrate by vacuum deposition technology. A method for making the amorphous alloy housing is also provided.

### BACKGROUND

1. Technical Field

The present disclosure relates to housings for electronic devices, and particularly, to a housing made of amorphous alloy and a method for making the same.

2. Description of Related Art

Amorphous alloys are well known for having similar structural characteristics as that of glass. The amorphous alloys have characteristics of high strength, high toughness, high corrosion resistance, and are easy to shape into complex structures. Thus, the amorphous alloys are widely used to make housings of a large variety of different electronic products such as mobile phones, MP3s, and PDAs. The housings that are made of the amorphous alloy can exhibit a special metallic luster surface finish after being treated by metal wire drawing process. However, the housings that have been treated by metal wire drawing process are easy to be scratched.

Therefore, there is room for improvement in the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the amorphous alloy housing and method for making the same. Moreover, in the drawings like reference numerals designate corresponding parts throughout the several views. Wherever possible, the same reference numerals are used throughout the drawings to refer to the same or like elements of an embodiment.

FIG. 1 shows a partial cross sectional view of an embodiment of an amorphous alloy housing.

FIG. 2 shows a flow chart of a method for making the amorphous alloy housing of the embodiment.

### DETAILED DESCRIPTION

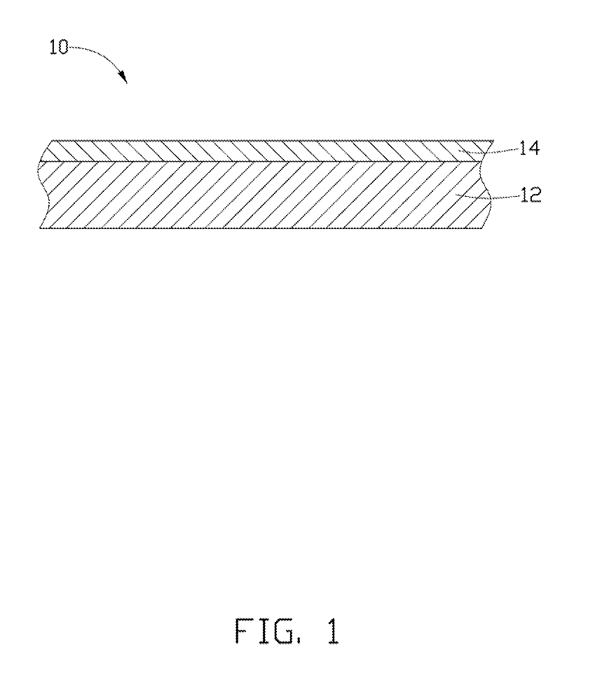

Referring to FIG. 1, an embodiment of an amorphous alloy housing 10 includes an amorphous alloy substrate 12 made of amorphous alloy material and a wear-resistant protective layer 14 formed on an outer surface of the amorphous alloy substrate 12 by vacuum deposition technology. It is to be understood that, the amorphous alloy housing 10 could be a housing or shell for such devices as a mobile phone, MP3, DVD player, or note book computer. A metal wire drawing process is applied to the amorphous alloy substrate 12 before the wear-resistant protective layer 14 is formed on the outer surface of the amorphous alloy substrate 12, to achieve different metallic luster surface finish.

In the illustrated embodiment, the amorphous alloy substrate 12 is made of zirconium (Zr)-based amorphous alloy. It is to be understood that, the amorphous alloy substrate 12 can also be made of iron (Fe)-based, cobalt (Co)-based, nickel (Ni)-based or other amorphous alloys.

In the illustrated embodiment, the wear-resistant protective layer 14 is a titanium nitride (TiN) protective layer, having a thickness of about 1.0˜2.0 μm. It is to be understood that the wear-resistant protective layer 14 can also be a titanium carbonitride (TiCN) layer, a titanium aluminum nitride (TiAlN) layer, a chromium nitride (CrN) layer, a diamond-like carbon (DLC) layer, or a titanium aluminum chromium nitride (TiAlCrN) layer.

In the illustrated embodiment, the wear-resistant protective layer 14 is deposited on the outer surface of the amorphous alloy substrate 12 by ion plating process. It is to be understood that the wear-resistant protective layer 14 can also be formed by evaporation, sputtering and other vacuum coating method.

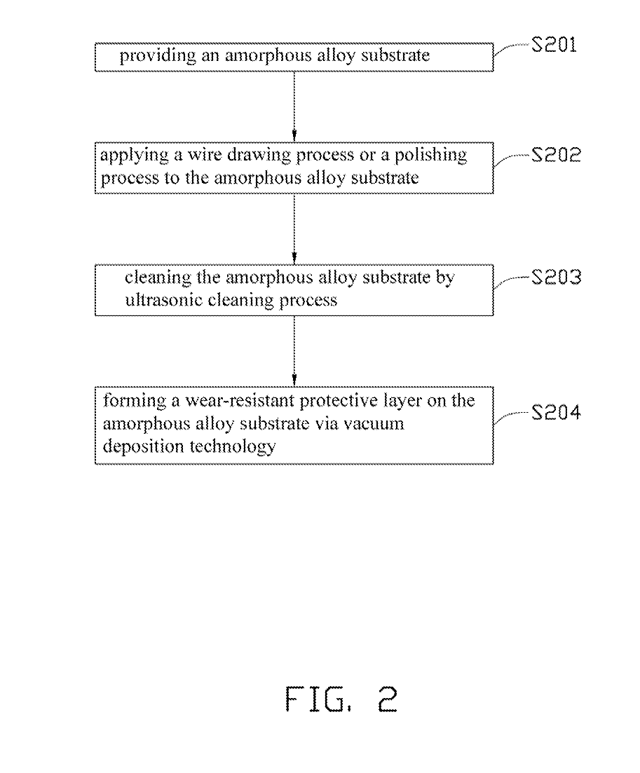

Referring to FIG. 2, a method for making the amorphous alloy housing 10 is illustrated as follows.

In step S201: an amorphous alloy substrate 12 is provided. In the illustrated embodiment, the amorphous alloy substrate 12 is made of bulk-solidifying amorphous alloy, which is made of Zr-based master alloy. Specifically, Zr-based master alloy can be formed by the following method: manufacturing the Nickel-Neodymium (Ni—Nb) alloy by vacuum arc melting furnace, and melting the Ni—Nb alloy by using a vacuum induction furnace, and adding zirconium (Zr), copper (Cu), aluminum (Al) and other elements into the vacuum induction furnace to finally obtain the Zr-based master alloys. The amorphous alloy substrate 12 is formed by die-casting method. For example, a method for manufacturing the amorphous alloy substrate 12 includes following steps. First, the Zr-based master alloy is provided. Second, the Zr-based master alloy is heated to around the glass transition temperature of the bulk-solidifying amorphous alloy; and finally the Zr-based master alloy is die-casted or molded to form the amorphous alloy substrate 12.

In step S202: a metal wire drawing process or a polishing process is applied to the amorphous alloy substrate 12 to achieve different metallic luster surface finishes.

In step S203: the amorphous alloy substrate 12 is cleaned by ultrasonic cleaning process by using anhydrous ethanol.

In step S204: a wear-resistant protective layer 14 is formed on the outer surface of the amorphous alloy substrate 12 by vacuum deposition technology. In one embodiment, the wear-resistant protective layer 14 is a TiN protective layer, having a thickness of about 1.0-2.0 μm formed on the amorphous alloy substrate 12 by ion plating process. The titanium atoms of the wear-resistant protective layer 14 is in a ratio of about 50% to 60%, and the nitrogen atoms is in a ratio of about 40% to 50%. A grain size of the titanium nitride of the wear-resistant protective layer 14 is in a range of about 50-100 nanometers. The ion plating process is performed in a vacuum chamber with vacuum less than 4×10⁻³ Pa, wherein, a chamber temperature of the vacuum chamber is in a range about 200-300° C., a rotation speed of a transfer frame is controlled between 0.5 r/min to 3.0 r/min, an input Ar gas flow rate is controlled at between 400˜600 standard cubic centimeters per minute (SCCM), a N₂ gas flow rate is controlled between 200˜300 SCCM, a Ti target power is in a range of 10˜14 Kw, a voltage bias is in a range of 80 v˜90 v, a duty ratio is in a range of 20%˜70%, and a sputtering time is controlled within about 3 to 4 hours.

One embodiment of the method for making the Zr-based amorphous alloy housing includes following steps. First, a Zr-based amorphous alloy substrate is provided. Second, a metal wire drawing process or a polishing process is applied to the Zr-based amorphous alloy substrate to achieve different metallic luster surface. Third, the Zr-based amorphous alloy substrate is cleaned by ultrasonic cleaning process by using anhydrous ethanol about 30 minutes; and finally the cleaned Zr-based amorphous alloy substrate is put into a vacuum chamber of a medium frequency magnetron sputtering film coating machine to form a TiN protective layer on the outer surface of the Zr-based amorphous alloy substrate. In one embodiment, during the TiN protective layer forming process, the vacuum of the vacuum chamber of the medium frequency magnetron sputtering film coating machine is controlled at 3×10⁻³ Pa with a vacuum pump, the chamber temperature of the vacuum chamber is controlled at 200, and the speed of the rotation of the transfer frame is controlled at 0.5 r/min; When the vacuum of the vacuum chamber is reached to 3×10⁻³ Pa, the working gas Ar and reactive gas N₂ are input into the vacuum chamber with a argon gas flow rate of about 400 SCCM and a nitrogen flow rate of about 200 SCCM; after that, controlling the Ti target power at 14 Kw, the bias at 80 v, the duty ratio at 20%, and the sputtering time to about 3 hours to finally form the TiN protective layer on the outer surface of the Zr-based amorphous alloy substrate.

Another embodiment of the method for making the Zr-based amorphous alloy housing includes following steps. First, a Zr-based amorphous alloy substrate is provided. Second, a metal wire drawing process or a polishing process is applied to the Zr-based amorphous alloy substrate to achieve different metallic luster surface finishes. Third, the Zr-based amorphous alloy substrate is cleaned by ultrasonic cleaning process by using anhydrous ethanol for about 30 minutes. Finally, the cleaned Zr-based amorphous alloy substrate is put into a vacuum chamber of a medium frequency magnetron sputtering film coating machine to form a TiN protective layer on the outer surface of the Zr-based amorphous alloy substrate. In one embodiment, during the TiN protective layer forming process, the vacuum of the vacuum chamber of the medium frequency magnetron sputtering film coating machine is controlled at 3×10⁻³ Pa using a vacuum pump, the chamber temperature of the vacuum chamber is controlled at 300, and the rotation speed of the transfer frame is controlled at 3.0 r/min. When the vacuum of the vacuum chamber has reached 3×10⁻³ Pa, the working gas Ar and the reactive gas N₂ are inputted into the vacuum chamber along with a argon gas flow rate of about 600 SCCM and a nitrogen flow rate of about 300 SCCM. After that, the Ti target power at 10 Kw, the bias at 90 v, the duty ratio at 70%, and the sputtering time to about 4 hours are configured or controlled to finally form the TiN protective layer on the outer surface of the Zr-based amorphous alloy substrate.

A wear resistance test method performed to the Zr-based amorphous alloy housing and the Zr-based amorphous alloy substrate includes the following steps. First, two scraping rubber heads are respectively provided to scrape one surface of the Zr-based amorphous alloy housing and the Zr-based amorphous alloy substrate, the two scraping rubber heads are moved with a speed of 25 mm/min, and a pressing force applied to the two rubber scraping heads is substantially one kilogram. Second, the surfaces of the Zr-based amorphous alloy housing and the Zr-based amorphous alloy substrate are respectively checked after being scraped back and forth about 10 times, 20 times and 100 times, and the testing results show that as the scraping count increase, the Zr-based amorphous alloy substrate surface becomes worn. However, the Zr-based amorphous alloy housing surface remains having similar surface finish as that in the original state. Thus, when comparing the amorphous alloy housing made by the aforementioned method with the traditional amorphous alloy housing, we find that, the amorphous alloy housing made by the aforementioned method has a better wear resistance.

An adhesion testing method performed to the Zr-based amorphous alloy housing includes the following steps. An adhesive tape such as 3M-600 (from 3M company) is adhered to the Zr-based amorphous alloy housing, and then the adhesive tape is rapidly pulled off to check the cut edge of the adhesive tape. The test result shows that the cut edge of the adhesive tape is perfectly smooth, and the adhesion of the Zr-based amorphous alloy housing reaches to within a 5B of ISO standard.

Three random points of the Zr-based amorphous alloy housing and the Zr-based amorphous alloy substrate are respectively chosen to perform the Vickers-hardness test. The testing results show that an average hardness of the amorphous alloy housing made by the aforementioned method reaches to 623.2 HV, which is higher when compared to that of the average hardness of the traditional amorphous alloy housing of 484.3 HV. Therefore, the Zr-based amorphous alloy housing has improved hardness over traditional amorphous alloy housing.

It is to be understood, however, that even through numerous characteristics and advantages of the disclosure have been set forth in the foregoing description, together with details of the structure and function of the present disclosure, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. An amorphous alloy housing, comprising:
an amorphous alloy substrate; and
a wear-resistant protective layer formed on an outer surface of the amorphous alloy substrate by vacuum deposition technology.

2. The amorphous alloy housing of claim 1, wherein the amorphous alloy substrate is made of zirconium-based amorphous alloy.

3. The amorphous alloy housing of claim 1, wherein the amorphous alloy substrate is made of iron-based, cobalt-based or nickel-based amorphous alloy.

4. The amorphous alloy housing of claim 1, wherein the wear-resistant protective layer is a titanium nitride protective layer.

5. The amorphous alloy housing of claim 4, wherein a thickness of the wear-resistant protective layer is in a range of 1.0˜2.0 μm.

6. The amorphous alloy housing of claim 1, wherein the wear-resistant protective layer is selected from a group consisting of a titanium carbonitride layer, a titanium aluminum nitride layer, a chromium nitride layer, a diamond-like carbon layer and an titanium aluminum chromium nitride layer.

7. The amorphous alloy housing of claim 4, wherein the titanium atoms of the wear-resistant protective layer is in a ratio of about 50% to 60%, and the nitrogen atoms is in a ratio of about 40% to 50%.

8. The amorphous alloy housing of claim 4, wherein a grain size of the titanium nitride of the wear-resistant protective layer is in a range of about 50-100 nanometers.

9. A method for making an amorphous alloy housing, comprising the following steps:
providing an amorphous alloy substrate;
applying a wire drawing process or a polishing process to the amorphous alloy substrate; and
forming a wear-resistant protective layer on an outer surface of the amorphous alloy substrate by vacuum deposition technology.

10. The method for making amorphous alloy housing of claim 9, further comprising a step of cleaning the amorphous alloy substrate by ultrasonic cleaning process before the step of forming the wear-resistant protective layer on the outer surface of the amorphous alloy substrate.

11. The method for making amorphous alloy housing of claim 9, wherein the amorphous alloy substrate is made of zirconium-based master alloy.

12. The method for making amorphous alloy housing of claim 11, wherein the zirconium-based master alloy is formed by the following steps: manufacturing the Nickel-Neodymium alloy by vacuum arc melting furnace, melting the Nickel-Neodymium alloy by using a vacuum induction furnace and adding zirconium, copper, and aluminum elements into the vacuum induction furnace to obtain the zirconium-based master alloy.

13. The method for making amorphous alloy housing of claim 9, wherein the amorphous alloy substrate is formed by following steps: providing a zirconium-based master alloy; heating the zirconium-based master alloy to around the glass transition temperature thereof; and die-casting or molding the zirconium-based master alloy to form the amorphous alloy substrate.

14. The method for making amorphous alloy housing of claim 9, wherein the wear-resistant protective layer is a titanium nitride protective layer, having a thickness of about 1.0˜2.0 μm formed on the amorphous alloy substrate by ion plating process.

15. The method for making amorphous alloy housing of claim 14, wherein the titanium atoms of the wear-resistant protective layer is in a ratio of about 50% to 60%, and the nitrogen atoms is in a ratio of about 40% to 50%.

16. The method for making amorphous alloy housing of claim 14, wherein a grain size of the titanium nitride of the wear-resistant protective layer is in a range of about 50-100 nanometers.

17. The method for making amorphous alloy housing of claim 14, wherein the ion plating process is performed in a vacuum chamber with vacuum≦4×10⁻³ Pa, a chamber temperature of the vacuum chamber is 200˜300° C., a rotation speed of a transfer frame is controlled at 0.5 to 3.0 r/min, an input Ar gas flow rate is 400˜600 SCCM, a N₂ gas flow rate is 200˜300 SCCM, the Ti target power is 10˜14 Kw, the voltage bias is 80˜90 v, the duty ratio is 20%˜70%, and a sputtering time is controlled within 3 to 4 hours.
